(19) United States
(12) Patent Application Publication
(10) Pub. No.: US 2024/0213236 A1
(43) Pub. Date: Jun. 27, 2024

(54) INTEGRATED CIRCUIT PACKAGE AND METHOD

(71) Applicant: Taiwan Semiconductor Manufacturing Co., Ltd., Hsinchu (TW)

(72) Inventors: Shu-Yan Jhu, Hsinchu (TW); Kuo-Chiang Ting, Hsinchu (TW); Sung-Feng Yeh, Taipei City (TW)

(21) Appl. No.: 18/151,629

(22) Filed: Jan. 9, 2023

Related U.S. Application Data
(60) Provisional application No. 63/477,284, filed on Dec. 27, 2022.

(51) Int. Cl. H01L 25/18; H01L 21/56; H01L 23/00; H01L 23/36; H01L 23/48

(52) U.S. Cl. CPC H01L 25/18; H01L 21/56; H01L 23/36; H01L 23/481; H01L 24/05; H01L 24/08; H01L 24/29; H01L 24/32; H01L 24/80; H01L 2224/05647; H01L 2224/08146; H01L 2224/29186; H01L 2224/32245; H01L 2224/80379; H01L 2224/80895; H01L 2224/80896

(57) ABSTRACT

A semiconductor device includes a first semiconductor package comprising: a first interconnect structure on a first semiconductor substrate; through substrate vias electrically coupled to the first interconnect structure extending through the first semiconductor substrate; and a second semiconductor package directly bonded to the first semiconductor package, the second semiconductor package comprising a second semiconductor substrate and a second interconnect structure on the second semiconductor substrate. The semiconductor device further includes a silicon layer on a surface of the second semiconductor package that is opposite to the first semiconductor package; and a heat dissipation structure attached to the silicon layer.

### PRIORITY CLAIM AND CROSS-REFERENCE

This application claims the benefit of U.S. Provisional Application No. 63/477,284, entitled: “Integrated Circuit Package and Method,” filed on Dec. 27, 2022, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB). The high level of integration and component density may result in increased heat generation within the PoP device that necessitates creative packaging techniques that integrate improved heat dissipation features to maintain the enhanced functionalities of these PoP devices while maintaining their small footprints.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view a first carrier substrate containing alignment marker features utilized during intermediate steps of manufacturing a semiconductor package in accordance with some embodiments.

FIGS. 2, 3, 4 and 5 illustrate cross-sectional views of intermediate steps in forming a first semiconductor device over the carrier substrate in accordance with some embodiments.

FIG. 6 illustrates a cross-sectional view of a second semiconductor device formed over the first semiconductor device forming a Package-on-Package (PoP) device in accordance with some embodiments.

FIG. 7 illustrates a cross-sectional view of a formation of a first silicon layer over the second semiconductor device and a thinning of the first silicon layer in accordance with some embodiments.

FIG. 8 illustrates a cross-sectional view of a formation of an oxide layer over the first silicon layer in accordance with some embodiments.

FIG. 9 illustrates a cross-sectional view of a formation of a first heat dissipation structure in accordance with some embodiments.

FIG. 10 illustrates a cross-sectional view of an alignment of the first heat dissipation structure over the oxide layer in accordance with some embodiments.

FIG. 11 illustrates a cross-sectional view of an attachment of the first heat dissipation structure to the PoP device in accordance with some embodiments.

FIG. 12 illustrates a cross-sectional view of a removal of the first carrier substrate in accordance with some embodiments.

FIGS. 13 and 14 illustrate cross-sectional views of a steps forming external contacts for the PoP device in accordance with some embodiments.

FIG. 15 illustrates a cross-sectional view of a formation of a first buffer layer over the PoP device in accordance with some embodiments.

FIG. 16 illustrates a cross-sectional view of a formation of a second silicon layer over the first buffer layer and a thinning of the second silicon layer in accordance with some embodiments.

FIG. 17 illustrates a cross-sectional view of a formation of a second heat dissipation structure in accordance with some embodiments.

FIGS. 18 and 19 illustrate cross-sectional views of an alignment and attachment of the second heat dissipation structure to the PoP device in accordance with some embodiments.

FIGS. 20 and 21 illustrate cross-sectional views of a removal of the first carrier substrate and formation of external contacts for the PoP device in accordance with some embodiments.

FIG. 22 illustrates a cross-sectional view of a formation of a second buffer layer over the PoP device in accordance with some embodiments.

FIG. 23 illustrates a cross-sectional view of a formation of a metal bonding layer over the second buffer layer in accordance with some embodiments.

FIG. 24 illustrates a cross-sectional view of a formation of a third heat dissipation structure in accordance with some embodiments.

FIGS. 25 and 26 illustrate cross-sectional views of an alignment and attachment of the third heat dissipation structure to the PoP device in accordance with some embodiments.

FIGS. 27 and 28 illustrate cross-sectional views of a removal of the first carrier substrate and formation of external contacts for the PoP device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, stacked dies (e.g., a first die bonded to a second die) and a heat dissipation structure (e.g., a substrate) is bonded to a backside of the second die. In some embodiments, the heat dissipation structure is bonded using an oxide-to-oxide bonding configuration. In some other embodiments, the heat dissipation structure is bonded using metal-to-metal bonding configuration. In other embodiments, the heat dissipation structure is bonded using another bonding configuration (e.g., dielectric-to-dielectric bonding, semiconductor-to-semiconductor bonding, or the like). These bonding configurations improve the heat dissipation in the completed package and improves adhesion between the heat dissipation structure and the second die.

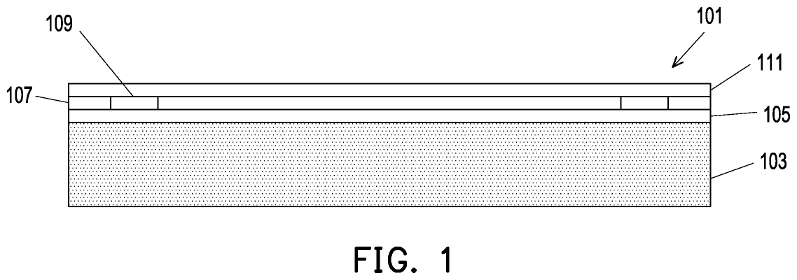

In FIG. 1, a first carrier substrate 101 is illustrated. In some embodiments the first carrier substrate 101 comprises a base substrate 103, a first dielectric layer 105 over a top surface of the base substrate 103; a release layer 107 over the first dielectric layer 105; and first alignment marks 109 embedded within the release layer 107. Further, a first bonding layer 111 may be deposited over a top surface of the release layer 107, covering the first alignment marks 109. The first carrier substrate 101 may subsequently facilitate the formation of multiple semiconductor devices (e.g. a Package-on-Package (PoP) device) on the first carrier substrate 101.

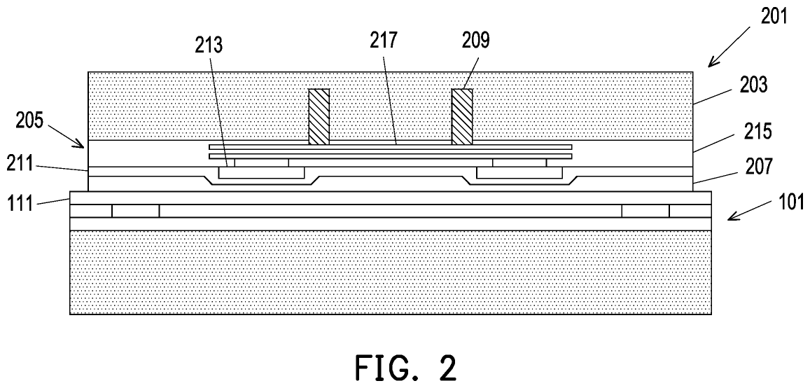

In accordance with some embodiments, the base substrate 103 may comprise silicon (e.g. a glass carrier substrate, a ceramic carrier substrate, or the like). In some embodiments, the first dielectric layer 105 may comprise silicon oxide, silicon nitride, silicon oxynitride, a polymer, or the like and be deposited by physical vapor deposition (PVD), chemical vapor deposition (CVD), atomic layer deposition (ALD), or the like. In some embodiments, the release layer 107 may comprise an epoxy-based thermal-release material, which loses its adhesive property when heated, such as a light-to-heat-conversion (LTHC) release coating; an ultra-violet (UV) glue, which loses its adhesive property when exposed to UV light; or the like. Further, the first alignment marks 109 may comprise a first conductive material. The first alignment marks 109 are disposed within the first dielectric layer 105 and may facilitate accurate placement of subsequent structures (e.g. a first semiconductor die 201, see FIG. 2) on the first carrier substrate 101. In accordance with some embodiments, the first bonding layer 111 may comprise a silicon-containing dielectric material such as silicon oxide, silicon nitride, silicon oxynitride, or the like, and the first bonding layer 111 may be deposited using a suitable deposition process such as CVD, PVD, ALD, high-density plasma chemical vapor deposition (HDPCVD), oxidation of the underlying material, combinations of these, or the like. Optionally, a planarization step may then be performed to level a top surface of the first bonding layer 111 such that the first bonding layer 111 has a high degree of planarity. Other materials and formation methods are also possible.

In FIG. 2, the first semiconductor die 201 is attached to the first carrier substrate 101. In some embodiments the first semiconductor die 201 comprises a first interconnect structure 205 on a first semiconductor substrate 203. The first semiconductor die 201 may be attached to the first carrier substrate 101 by a second bonding layer 207 such that the first interconnect structure 205 faces the first carrier substrate 101.

The first semiconductor die 201 may be a bare chip semiconductor die (e.g., an unpackaged semiconductor die). For example, the first semiconductor die 201 may be a logic die (e.g., application processor (AP), central processing unit, microcontroller, etc.), a memory die (e.g., dynamic random access memory (DRAM) die, hybrid memory cube (HBC), static random access memory (SRAM) die, a wide input/output (wideIO) memory die, magnetoresistive random access memory (mRAM) die, resistive random access memory (rRAM) die, etc.), a power management die (e.g., power management integrated circuit (PMIC) dies), a radio frequency (RF) die, a sensor die, a micro-electro-mechanical-system (MEMS) die, a signal processing die (e.g., digital signal processing (DSP) die), a front-end die (e.g., analog front-end (AFE) die), a biomedical die, or the like.

The first semiconductor die 201 may be processed according to applicable manufacturing processes to form integrated circuits in the first semiconductor die 201. For example, the first semiconductor die 201 may include a first semiconductor substrate 203, such as silicon, doped or undoped, or an active layer of a semiconductor-on-insulator (SOI) substrate. The first semiconductor substrate 203 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Devices, such as transistors, diodes, capacitors, resistors, or the like, may be formed in and/or on the first semiconductor substrate 203 and may be interconnected by the first interconnect structure 205 which comprises first metallization patterns 217 (e.g., conductive lines and vias) in one or more first interconnect dielectric layers 215 to form one or more integrated circuits. The first interconnect dielectric layers 215 may comprise silicon oxide, silicon nitride, silicon oxynitride, a polymer, or the like and be deposited by PVD, CVD, ALD, or the like. The first metallization patterns 217 may be conductive features formed in the first interconnect dielectric layers 215 by damascene processes, for example.

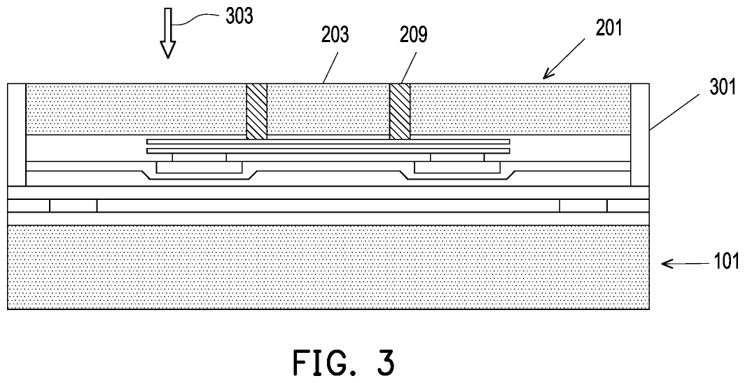

The first semiconductor die 201 further includes through substrate vias (TSVs) 209, which may be electrically connected to the metallization patterns in the first interconnect structure 205. The TSVs 209 may comprise a conductive material (e.g., copper, or the like) and may extend from the first interconnect structure 205 into the first semiconductor substrate 203. Insulating barrier layers (not separately illustrated) may be formed around at least portions of the TSVs 209 in the first semiconductor substrate 203. The insulating barrier layers may comprise, for example, silicon oxide, silicon nitride, silicon oxynitride, or the like, and may be used to physically and electrically isolate the TSVs 209 from the first semiconductor substrate 203. In subsequent processing steps, the first semiconductor substrates 203 may be thinned to expose the TSVs 209 (see FIG. 3). After thinning, the TSVs 209 provide electrical connection from a back side of the first semiconductor substrates 203 to a front side of the first semiconductor substrates 203.

The first semiconductor die 201 further comprises first contact pads 213, which allow external connections are made to the first interconnect structure 205 and the devices on the first semiconductor substrate 203. The first contact pads 213 may comprise copper, aluminum (e.g., 28K aluminum), or another conductive material that are electrically connected to the metallization patterns of the first interconnect structure 205. The first contact pads 213 are disposed on what may be referred to as an active side or front side of the first semiconductor die 201. The active side/front side of the first semiconductor die 201 may refer to a side of the first semiconductor substrate 203 on which the active devices are formed. The back side of the first semiconductor die 201 may refer to a side of the first semiconductor substrate 203 opposite the active side/front side.

A first passivation film 211 is disposed on the first interconnect structure 205, and the first contact pads 213. The first passivation film 211 may comprise silicon oxide, silicon oxynitride, silicon nitride, or the like, which may be deposited by CVD, ALD, PVD, or the like.

The first semiconductor die 201 may be formed as part of a larger wafer (e.g., connected to other first semiconductor dies 201). In some embodiments, the first semiconductor die 201 may be singulated from each other prior to packaging. The singulation process may include mechanical sawing, laser dicing, plasma dicing, combinations thereof, or the like. In other embodiments, the first semiconductor die 201 is singulated after they are integrated into a semiconductor package. For example, the first semiconductor die 201 may be packaged while still connected as part of a wafer.

In some embodiments, the second bonding layer 207 is deposited on the first semiconductor die 201, such as on the first passivation layer 207. The second bonding layer 207 may be formed in a similar manner and from a similar material as the first bonding layer 111.

In an embodiment the second bonding layer 207 is bonded to the first bonding layer 111 by a first dielectric-to-dielectric bonding process (e.g. oxide-to-oxide bonding). The fusion bond may be initiated by activating the first bonding layer 111 and/or the second bonding layer 207 followed by applying pressure, heat and/or other bonding process steps to join the first bonding layer 111 to the second bonding layer 207 surfaces. The activating the first bonding layer 111 and the second bonding layer 207 may be performed using, e.g., a dry treatment, a wet treatment, a plasma treatment, exposure to H₂, exposure to N₂, exposure to O₂, combinations of these, or the like. In embodiments where a wet treatment is used, an RCA cleaning process may be used, for example. The activating assists in the fusion bonding of the first bonding layer 111 and the second bonding layer 207 by, e.g., allowing the use of lower pressures and temperatures in subsequent fusion bonding processes. Through the treatment, the number of OH groups at surface(s) of the first bonding layer 111 and/or the second bonding layer 207 increases. After surfaces of the first bonding layer 111 and/or the second bonding layer 207 are activated, the first bonding layer 111 and the second bonding layer 207 may be contacted together at a relatively low temperature (e.g., room temperature) to form weak bonds. Subsequently, an annealing is performed to strengthen the weak bonds and form a fusion bond. During the annealing, the H of the OH bonds is outgassed, thereby forming Si—O—Si bonds between the first bonding layer, thereby strengthening the bonds.

In FIG. 3, the first semiconductor die 201 is encapsulated in a first encapsulant 301, and a first planarization process 303 is performed on the first semiconductor die 201 and the first encapsulant 301. In some embodiments, the first encapsulant 301 may be applied by compression molding, transfer molding, or the like, and may be formed over and around the first semiconductor die 201. The first encapsulant 301 may be applied in liquid or semi-liquid form and then subsequently cured. The first encapsulant 301 may be a molding compound. After the first encapsulant 301 is formed, the first planarization process 303 may be performed. In some embodiments, the first planarization process 303 may remove portions of the first encapsulant 301 over the first semiconductor die 201 and may thin the first semiconductor substrate 203 to expose the TSVs 209. The first planarization process 303 may be a mechanical grinding or chemical-mechanical polish (CMP) process whereby chemical etchants and abrasives are utilized to react and grind away the portions of the first encapsulant 301 and the semiconductor material of the first semiconductor substrate 203. However, any suitable planarization process may be utilized.

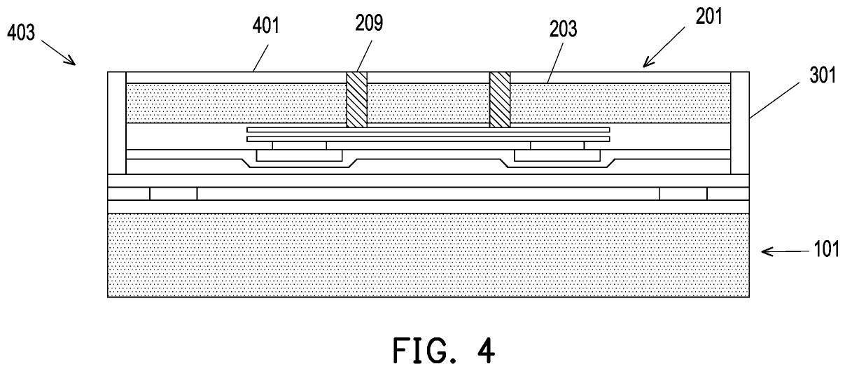

In FIG. 4, portions of the first semiconductor substrate 203 may be further removed to form recesses. The recesses may be formed so that a backside of the first semiconductor substrate 203 is disposed at a lower level than a top surface of the first encapsulant 301. The recesses may subsequently be filled by an isolation layer 401. In accordance with some embodiments, the recesses are formed in the first semiconductor substrate 203 utilizing an etching process that selectively etches the first semiconductor substrate 203 without significantly etching the TSVs 209 or the first encapsulant 301. As a result, the TSVs 209 may extend above the recesses in the first semiconductor substrate 203. In some embodiments an isolation material may be formed in the recesses forming the isolation layer 401. The isolation layer 401 is formed of a dielectric material. The dielectric material can be an oxide such as silicon oxide, phosphosilicate glass (PSG), borosilicate glass (BSG), boron-doped phosphosilicate glass (BPSG), a tetraethyl orthosilicate (TEOS) based oxide, or the like, which may be formed by a suitable deposition process such as CVD, ALD, or the like. Other suitable dielectric materials, such as a low temperature polyimide material, polybenzoxazole (PBO), an encapsulant, combinations thereof, or the like may also be utilized. The isolation layer 401 may isolate the TSVs 209 and the semiconductor material of the first semiconductor substrate 203. The first encapsulant 301 and the first semiconductor die 201 with the isolation layer 401 form a first semiconductor device 403 over the first carrier substrate 101.

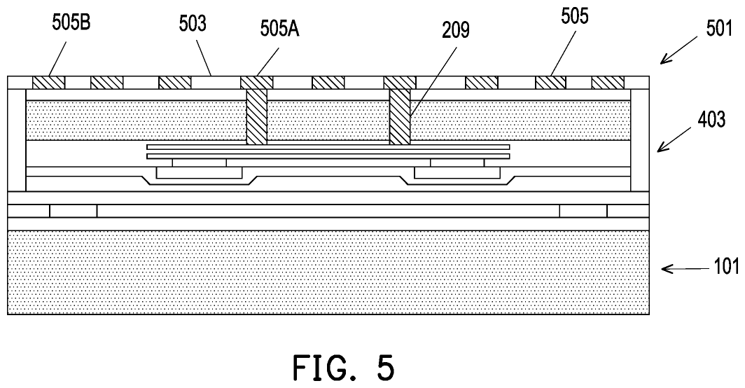

In FIG. 5, a third bonding layer 501 is formed over a backside surface of the first semiconductor device 403 and on the first encapsulant 301, the third bonding layer 501 may comprise a second dielectric layer 503 and first bond pads 505 embedded within the second dielectric layer 503. In some embodiments, the first bond pads 505 may comprise a conductive material such as copper, or the like. Some of the first bond pads 505 may be physically and electrically coupled to the TSVs 209. In an embodiment, the second dielectric layer 503 may comprise a silicon-containing dielectric material such as silicon oxide, silicon nitride, silicon oxynitride, or the like, and the third dielectric layer 611 may be deposited using a suitable deposition process such as CVD, PVD, ALD, HDPCVD, combinations of these, or the like. Optionally, a planarization step may then be performed to level a top surface of the third bonding layer 501 such that the third bonding layer 501 has a high degree of planarity. Other materials and formation methods are also possible.

In accordance with some embodiments, the first bond pads 505 may be formed over the isolation layer 401 and TSVs 209. As an example, to form the first bond pads 505, a seed layer is formed over a top surface of the isolation layer 401 and the TSVs 209. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the first bond pads 505. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the first bonding pads 505. Further, the second dielectric layer 503 may be formed by spin coating, lamination, CVD, the like, or a combination thereof after the formation of the first bond pads 505.

In some embodiments, the second dielectric layer 503 is formed before the first bond pads 505. The second dielectric layer 503 may be formed over the isolation layer 401 by spin coating, lamination, CVD, the like, or a combination thereof. The first bond pads 505 may be formed in the second dielectric layer 503 by forming recesses (not separately illustrated) in the second dielectric layer 503, for example, etching, milling, laser techniques, a combination thereof, or the like. A thin barrier layer (not separately illustrated) may be conformally deposited in the recesses, such as by CVD, ALD, PVD, thermal oxidation, a combination thereof, or the like. The barrier layer may be formed from an oxide, a nitride, a carbide, combinations thereof, or the like. A third conductive material may be deposited over the barrier layer and in the recesses. The third conductive material may be formed by an electro-chemical plating process, CVD, ALD, PVD, a combination thereof, or the like. Examples of the third conductive materials include copper, tungsten, aluminum, silver, gold, a combination thereof, or the like. Excess conductive material and the barrier layer is removed from a surface of the second dielectric layer 503, for example, by a CMP. The remaining portions of the barrier layer and the third conductive material in the recesses form the first bond pads 505.

In accordance with some embodiments, the first bond pads 505 may comprises both active bond pads 505A as well as dummy bond pads 505B. The dummy bond pads 505B are electrically isolated from other conductive features (including the electrical circuitry within the first semiconductor die 201 and the second semiconductor die 605), and the active bond pads 505A are actively utilized in the bonding of other conductive features to the first bond pads 505. The dummy bond pads 505B may be used to provide a uniform pattern density within the bonding layer

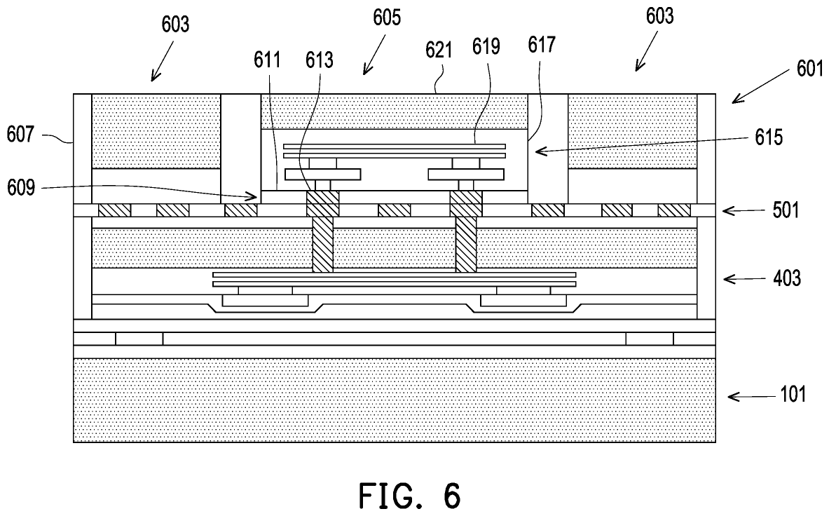

In FIG. 6, a second semiconductor die 605 and one or more dummy dies 603 are attached to the first semiconductor device 403 by the third bonding layer 501.

In accordance with some embodiments, the dummy dies 603 may be placed to provide structural support to the second semiconductor device 601 and reduce warping or cracking, particularly when multiple integrated circuit dies are attached to the third bonding layer 501. The dummy dies 603 may be formed of a material that has a suitable mechanical stiffness or rigidity. In some embodiments, the dummy dies 603 may be formed from a semiconductor material such as silicon, silicon carbide, gallium arsenide, gallium phosphide, indium phosphide, indium arsenide, indium antimonide, the like, or combinations thereof. In some embodiments, the dummy dies 603 may be formed from a dielectric material such as a ceramic material, quartz, another electrically inert material, the like, or combinations thereof. In some embodiments, the dummy dies 603 may be a metal or metal alloy, such as a tin-nickel alloy (e.g., “Alloy 42”) or the like. In some embodiments, the dummy dies 603 are formed from two or more different materials, such as multiple layers of different materials. In some embodiments, the material of the dummy dies 603 is chosen based on the mechanical stiffness or rigidity of the material.

In some embodiments, the dummy dies 603 are included for improved uniformity in the second semiconductor device 601, which may result in improved planarization. The dummy dies 603 may also be included to reduce CTE mismatch amongst various features in the second semiconductor device 601. The dummy dies 603 may also as act as a heat dissipation feature. In such embodiments, a material of the dummy dies 603 may be selected to have a relatively high thermal conductivity (e.g., higher than a thermal conductivity than subsequently deposited second encapsulant 607). In accordance with some embodiments, the dummy dies 603 may be substantially free of any active devices, functional circuits, or the like. For example, the dummy dies 603 may include a dummy die substrate 603A (e.g., a bulk silicon substrate) and a dummy die bonding layer 603B. The dummy die bonding layer 603B may be used to bond the dummy dies 603 to the third bonding layer 501 using a fusion bonding process, such as the process used to bond the first and second bonding layers 111 and 207, for example.

The second semiconductor die 605 may be a bare chip semiconductor die (e.g., an unpackaged semiconductor die). For example, the second semiconductor die 605 may be a logic die (e.g., AP, central processing unit, microcontroller, etc.), a memory die (e.g., DRAM die, HBC, SRAM die, wideIO memory die, mRAM die, rRAM) die, etc.), a power management die (e.g., PMIC dies), a RF die, a sensor die, a MEMS die, a signal processing die (e.g., DSP die), a front-end die (e.g., AFE die), a biomedical die, or the like.

The second semiconductor die 605 may be processed according to applicable manufacturing processes to form integrated circuits in the second semiconductor die 605. For example, the second semiconductor die 605 may include a second semiconductor substrate 621, such as silicon, doped or undoped, or an active layer of a semiconductor-on-insulator (SOI) substrate. The second semiconductor substrate 621 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Devices, such as transistors, diodes, capacitors, resistors, or the like, may be formed in and/or on the second semiconductor substrate 621 and may be interconnected by the second interconnect structure 615which comprises second metallization patterns 619 (e.g., conductive lines and vias) in one or more second interconnect dielectric layers 617 to form one or more integrated circuits. The second interconnect dielectric layers 617 may comprise silicon oxide, silicon nitride, silicon oxynitride, a polymer, or the like and be deposited by PVD, CVD, ALD, or the like. The second metallization patterns 619 may be conductive features formed in the second interconnect dielectric layers 617 by damascene processes, for example.

The second semiconductor die 605 further comprises second contact pads 613, which allow external connections are made to the second interconnect structure 615 and the devices on the second semiconductor substrate 621. The second contact pads 613 may comprise copper, aluminum (e.g., 28K aluminum), or another conductive material that are electrically connected to the second metallization patterns 619 of the second interconnect structure 615. The second contact pads 613 are disposed on what may be referred to as an active side or front side of the second semiconductor die 605. The active side/front side of the second semiconductor die 605 may refer to a side of the second semiconductor substrate 621 on which the active devices are formed. The back side of the second semiconductor die 605 may refer to a side of the second semiconductor substrate 621 opposite the active side/front side.

The second semiconductor die 605 may be formed as part of a larger wafer (e.g., connected to other second semiconductor dies 605). In some embodiments, the second semiconductor die 605 may be singulated from each other prior to packaging. The singulation process may include mechanical sawing, laser dicing, plasma dicing, combinations thereof, or the like. In other embodiments, the second semiconductor die 605 is singulated after they are integrated into a semiconductor package. For example, the second semiconductor die 605 may be packaged while still connected as part of a wafer.

In accordance with some embodiments, the second semiconductor die 605 is attached to the third bonding layer 501 by a fourth bonding layer 609. The second semiconductor die 605 may be attached to the third bonding layer 501 concurrently, before, or after attaching the dummy dies 603 to the third bonding layer 501. The fourth bonding layer 609 may include a third dielectric layer 611 and the second contact pads 613. The third dielectric layer 611 may comprise a silicon-containing dielectric material such as silicon oxide, silicon nitride, silicon oxynitride, or the like and the third dielectric layer 611 may be deposited using a suitable deposition process such as CVD, PVD, ALD, HDPCVD, oxidation of the underlying material, combinations of these, or the like. The second contact pads 613 may be formed in a similar manner as the first bond pads 505. Optionally, a planarization step may then be performed to level a top surface of the fourth bonding layer 609 such that the fourth bonding layer 609 has a high degree of planarity. Other materials and formation methods are also possible.

In some embodiments, the second semiconductor die 605 is bonded to the third bonding layer 501 by a dielectric-to-dielectric and metal-to-metal bonding process performed between the third bonding layer 501 and the fourth bonding layer 609. In some embodiments, the dielectric-to-dielectric bonding process forms a direct bond (e.g. a fusion bond such as an oxide-to-oxide bond) between the second dielectric layer 503 and the third dielectric layer 611. Further, the metal-to-metal bonding process may directly bond the first bond pads 505 of the third bonding layer 501 to the second contact pads 613 of the second semiconductor die 605 through direct metal-to-metal bonding. Thus, electrical connection between the first semiconductor die 201 and the second semiconductor die 605 may be provided by the physical connection of the first bond pads 505 to the second contact pads 613. The dielectric-to-dielectric bonding process may start with applying a surface treatment to either or both of the second dielectric layer 503 and the third dielectric layer 611 facilitating a dielectric-to-dielectric bond between the second dielectric layer 503 and the third dielectric layer 611 (e.g. a such as an oxide-to-oxide bond). The surface treatment may include a plasma treatment. The plasma treatment may be performed in a vacuum environment. After the plasma treatment, the surface treatment may further include a cleaning process (e.g., a rinse with deionized water, or the like) that may be applied to either or both of the second dielectric layer 503 and the third dielectric layer 611. The dielectric-to-dielectric and metal-to-metal bonding process may then proceed to aligning the second contact pads 613 of the second semiconductor die 605 to the first bond pads 505 of the third bonding layer 501. Next, the dielectric-to-dielectric and metal-to-metal bonding process includes a pre-bonding step, during which the second semiconductor die 605 is put in contact with the third bonding layer 501. The pre-bonding may be performed at room temperature (e.g., between about 21° C. and about 25° C.). The dielectric-to-dielectric and metal-to-metal bonding process continues with performing an anneal, for example, at a temperature between about 150° C. and about 400° C. for a duration between about 0.5 hours and about 3 hours, so that the first bond pads 505 (e.g., copper) and the second contact pads 613 (e.g., copper) inter-diffuses to each other, and hence the direct metal-to-metal bonding is formed.

Further, in accordance with some embodiments, the one or more dummy dies 603 and the second semiconductor die 605 are encapsulated by a second encapsulant 607. The second encapsulant 607 may be deposited over the one or more dummy dies 603 and the second semiconductor die 605 and in gaps between the one or more dummy dies 603 and the second semiconductor die 605. The second encapsulant 607 may be formed in a similar manner as the first encapsulant 301 and may be a molding compound. In some embodiments the second encapsulant 607 may be thinned in a similar manner as the first encapsulant 301 such that the one or more dummy dies 603, the second semiconductor die 605, and the second encapsulant 607 share a planar top surface of the second semiconductor device 601.

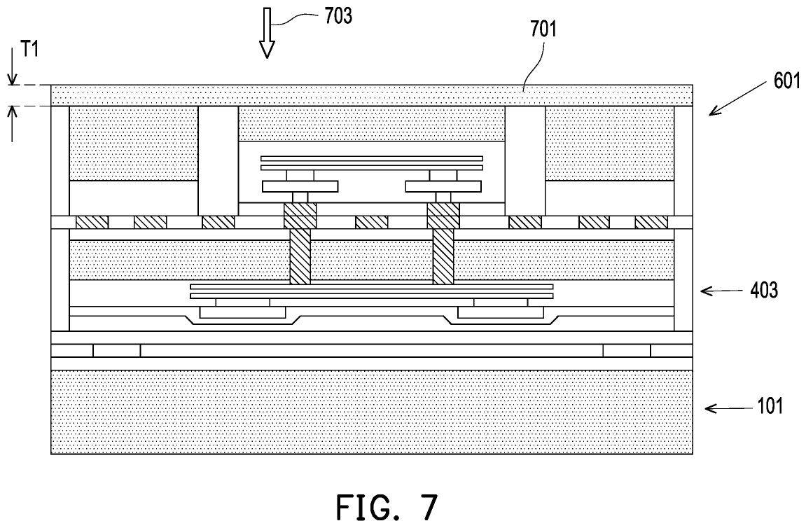

In FIG. 7, a first silicon layer 701 is formed over the second semiconductor device 601. In accordance with some embodiments, the first silicon layer 701 is formed by depositing silicon over the second semiconductor device 601 using CVD, HDPCVD, Flowable CVD, spin-on coating, or the like. The first silicon layer 701 is planarized by a second planarization process 703. In accordance with some embodiments, the second planarization process 703 may be a mechanical grinding, CMP process, or the like. The second planarization process 703 may reduce a thickness of the first silicon layer 701 to a first thickness T1 in a range of 0.05 μm to 5 μm. By forming the first silicon layer 701 to have the first thickness T1 discussed above, the first silicon layer 701 may achieve advantages, such as adequate thermal dissipation in the resulting structure.

The addition of adding the first silicon layer 701 improves the heat dissipation capabilities of the subsequently formed PoP device. The thermal conductivity of the first silicon layer 701 may allow for improved heat dissipation from heat generated from devices such as the first semiconductor die 201, the second semiconductor die 605, and other heat generating structures within the subsequently formed PoP device. As such, in some embodiments, the first silicon layer 701 may be formed in direct, physical contact with the second semiconductor substrate 621 of the second semiconductor die 605. The utilization of the first silicon layer 701 may allow for more powerful semiconductor dies to be incorporated into the PoP device while maintaining adequate temperatures within the PoP device as to avoid over-heating within the PoP device. Additionally, the utilization of the first silicon layer 701 may allow for improved heat dissipation while occupying a lower profile allowing for higher density packaging while improving or maintaining adequate heat dissipation as to reduce the risk of over-heating within the PoP device. Reducing the risk of over-heating the PoP device is advantageous as it may reduce the risk of thermal degradation within the PoP device as well as reduce the risk of reduced functionality of the PoP device that may be caused by over-heating.

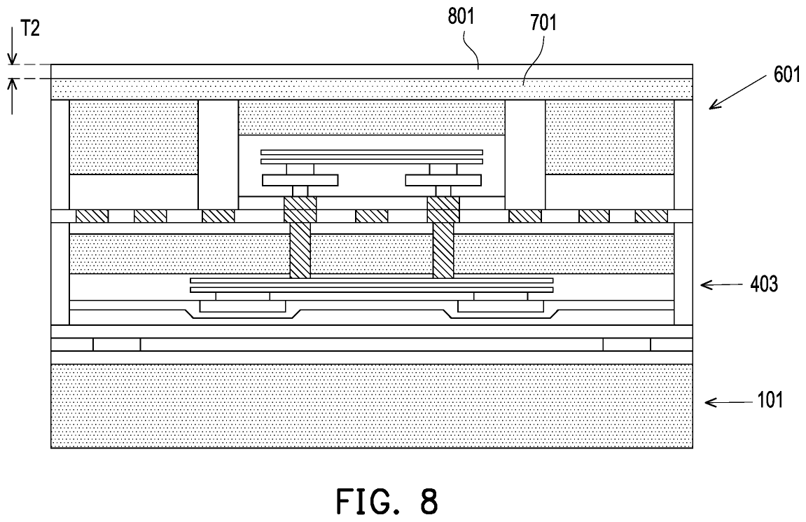

In FIG. 8, a first oxide layer 801 is formed over the top surface of the first silicon layer 701. The first oxide layer 801 may be formed by CVD, ALD, PVD, thermal oxidation, or the like. The first oxide layer 801 may comprise an oxide material such as silicon oxide, or the like. In some embodiments, the first oxide layer 801 has a second thickness T2 in a range of 0.05 μm to 3 μm. By forming the first oxide layer 801 to the range of the second thickness T2, advantages may be achieved. For example, the second thickness T2 may be sufficiently thin so as not to significantly insulate the second semiconductor device 601 while still providing adequate bonding capabilities.

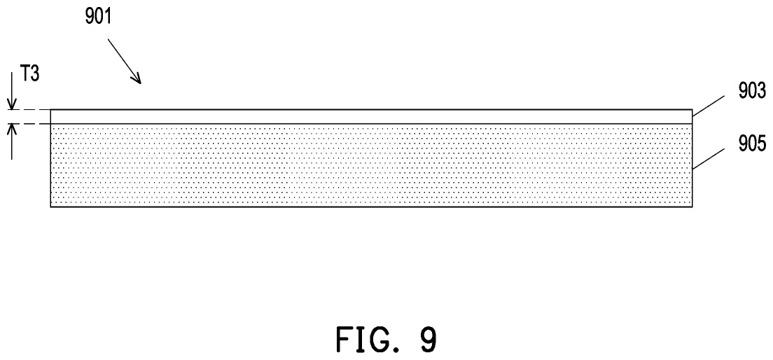

In FIG. 9, a first carrier structure 901 is illustrated where a second oxide layer 903 is formed over a second carrier substrate 905. In accordance with some embodiments, the second carrier substrate 905 comprises silicon, or the like. The second oxide layer 903 may be formed over the second carrier substrate 905 by CVD, ALD, PVD, thermal oxidation, or the like. The second oxide layer 903 may comprise an oxide material such as silicon oxide, or the like. The second oxide layer 903 may have a third thickness T3 in a range of 0.05 μm to 3 μm. In accordance with some embodiments, the first carrier structure 901 may act as a heat dissipation structure for the second semiconductor device 601 and the first semiconductor device 403. Further, the first carrier structure 901 may have a higher thermal conductivity than the second encapsulant 603. By forming the second oxide layer 903 to the range of the third thickness T3, advantages may be achieved. For example, the third thickness T3 may be sufficiently thin so as not to significantly insulate the second semiconductor device 601 while still providing adequate bonding capabilities.

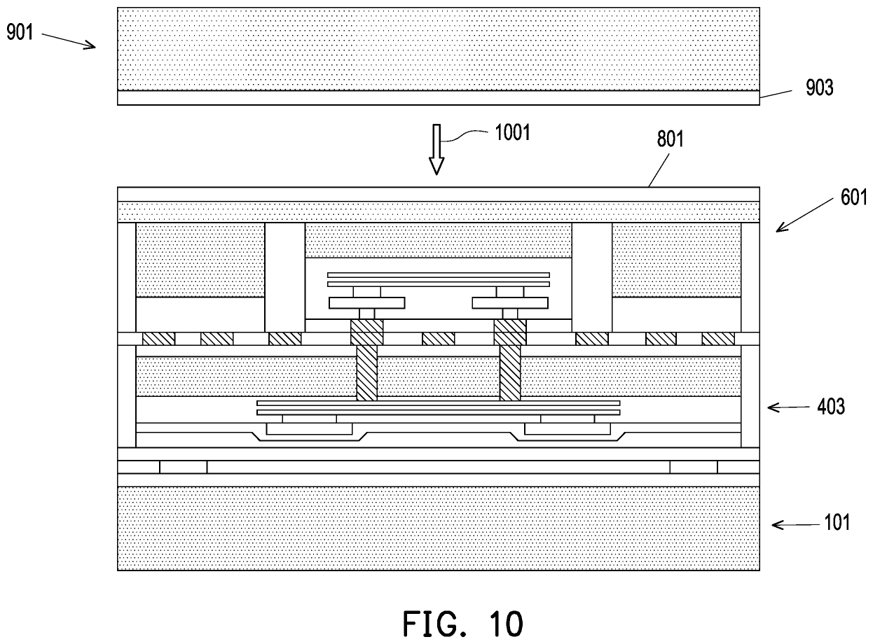

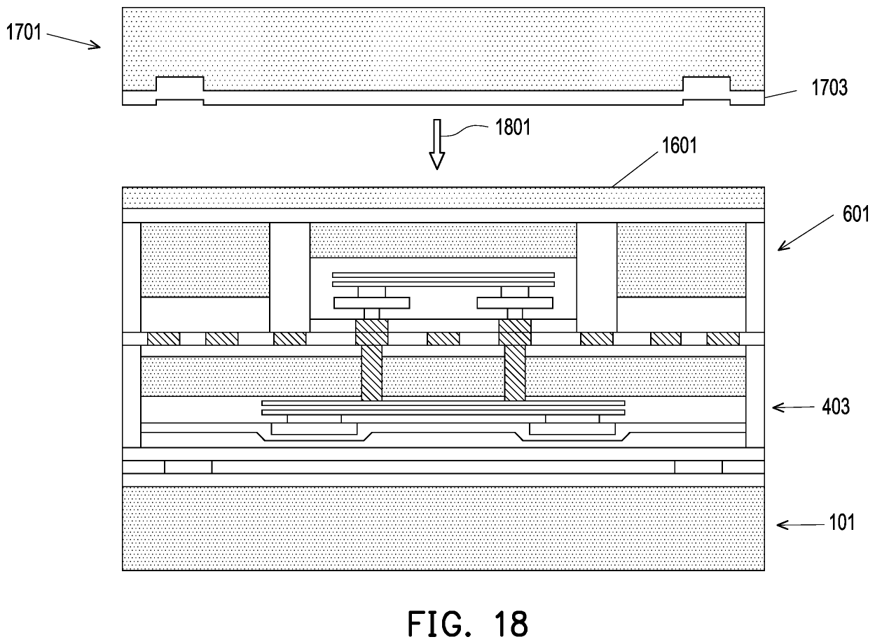

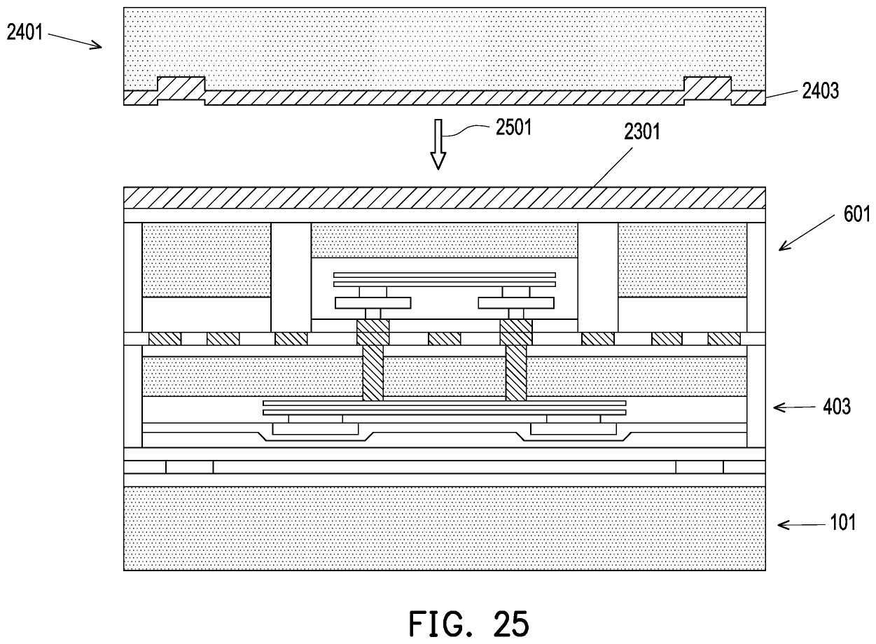

In FIG. 10, a first alignment process 1001 is performed to facilitate the attachment of the first carrier structure 901 to the first oxide layer 801. In an embodiment, a bottom surface of the first carrier structure 901 is aligned over a top surface of the first oxide layer 801 before bonding the first oxide layer 801 to the second oxide layer 903. In some embodiments, second alignment marks (not separately illustrated) may be utilized to facilitate the placement of the first carrier structure 901 onto the first oxide layer 801 so that the first carrier structure 901 is aligned with the second semiconductor device 601. An alignment process utilizing alignment marks in a similar manner as the first alignment process 1001 are depicted in greater detail in FIGS. 18 and 25.

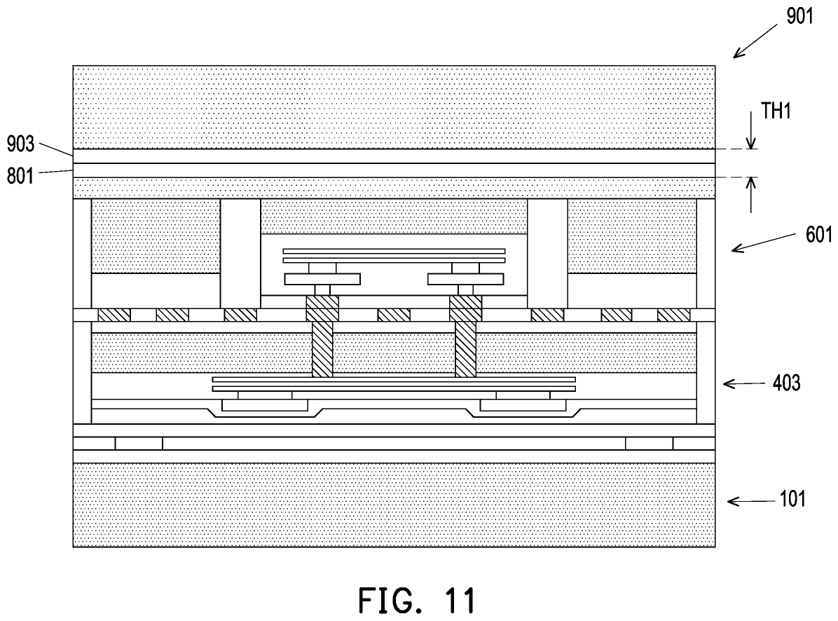

In FIG. 11, the first carrier structure 901 is attached to the second semiconductor device 601 by bonding the first oxide layer 801 to the second oxide layer 903. In accordance with some embodiments, the first oxide layer 801 is bonded to the second oxide layer 903 by a second fusion bonding process (e.g. oxide-to-oxide bonding). The fusion bond may be initiated by activating the first oxide layer 801 and the second oxide layer 903 followed by applying pressure, heat and/or other bonding process steps to join the first oxide layer 801 to the second oxide layer 903. The activating the first oxide layer 801 and the second oxide layer 903 may be performed by an activation step, the activation step, for example, may be a dry treatment, a wet treatment, a plasma treatment, exposure to H₂, exposure to N₂, exposure to O₂, combinations of these, or the like. In embodiments where a wet treatment is used, an RCA cleaning may be used, for example. In some embodiments, following the activation step, a pre-bonding step may be initiated by pressing the first oxide layer 801 against the second oxide layer 903. The pre-bonding step may be performed at room temperature (e.g. between about 21° C. and about 25° C.). In some embodiments, following the activation step, an annealing process may be applied by, for example, heating the first oxide layer 801 and the second oxide layer 903 at a temperature between about 150° C. and about 400° C. for a duration between about 0.5 hours and about 8 hours. Following the second fusion bonding process, the first oxide layer 801 and the second oxide layer 903 have a first combined thickness TH1 in a range of 0.1 μm to 6 μm. By bonding the first oxide layer 801 to the second oxide layer 903 such that the first oxide layer 801 and the second oxide layer 903 have the first combined thickness TH1 described above, advantages may be achieved, for example, the fusion bonded first oxide layer 801 to the second oxide layer 903 may be sufficiently thin so as not to significantly reduce thermal dissipation in the resulting package. It has been observed that when the combined thickness of the bonded first oxide layer 801 and the second oxide layer 903 is greater than the above range, thermal dissipation in the resulting structure may be unacceptably low.

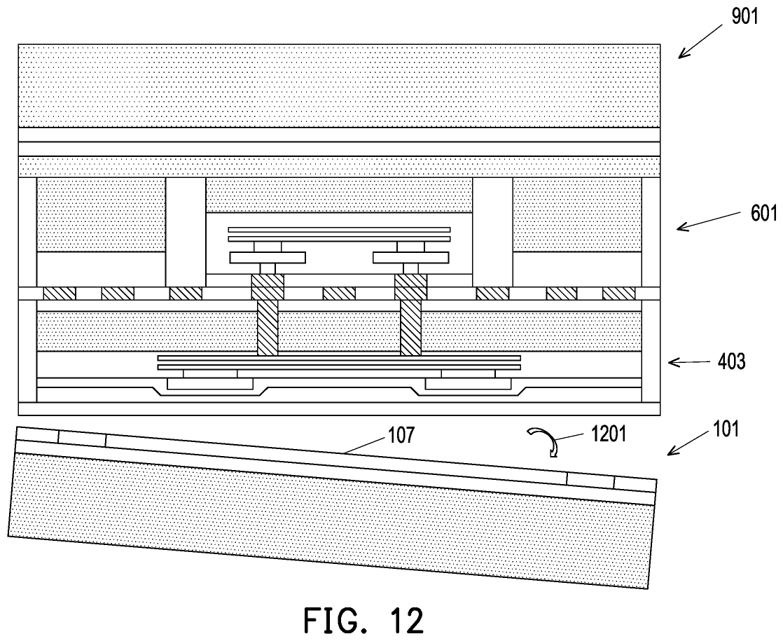

In FIG. 12, a debonding process 1201 is performed to remove the first carrier substrate 101 from the first semiconductor device 403. In an embodiment, the debonding includes projecting a light such as a laser light or an ultraviolet (UV) light on the release layer 107 so that the release layer 107 decomposes and the first carrier substrate 101 may be removed.

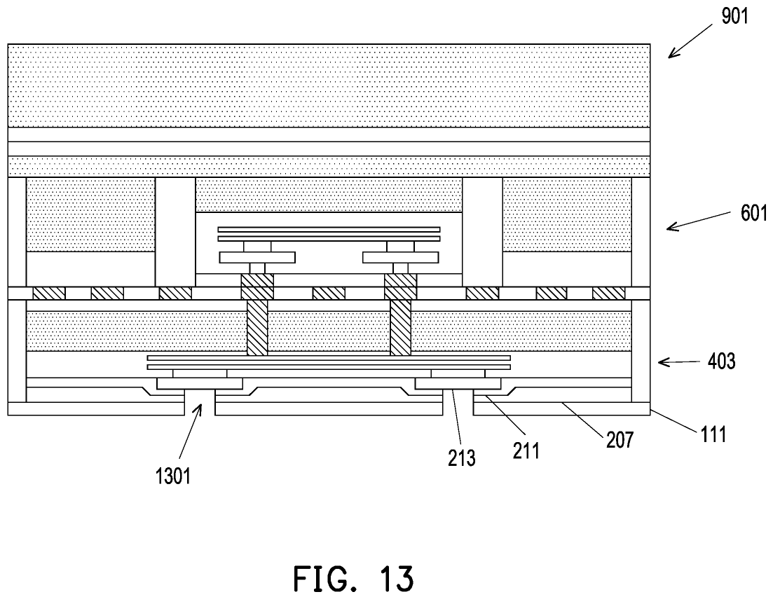

In FIG. 13, first openings 1301 are formed through the first bonding layer 111, the second bonding layer 207, and the first passivation layer 211 exposing the first contact pads 213. In some embodiments, the first openings 1301 are formed, for example, by etching, milling, laser techniques, a combination thereof, or the like, such that a bottom surface of the first contact pads 213 are exposed through the first bonding layer 111, the second bonding layer 207, and the first passivation layer 211.

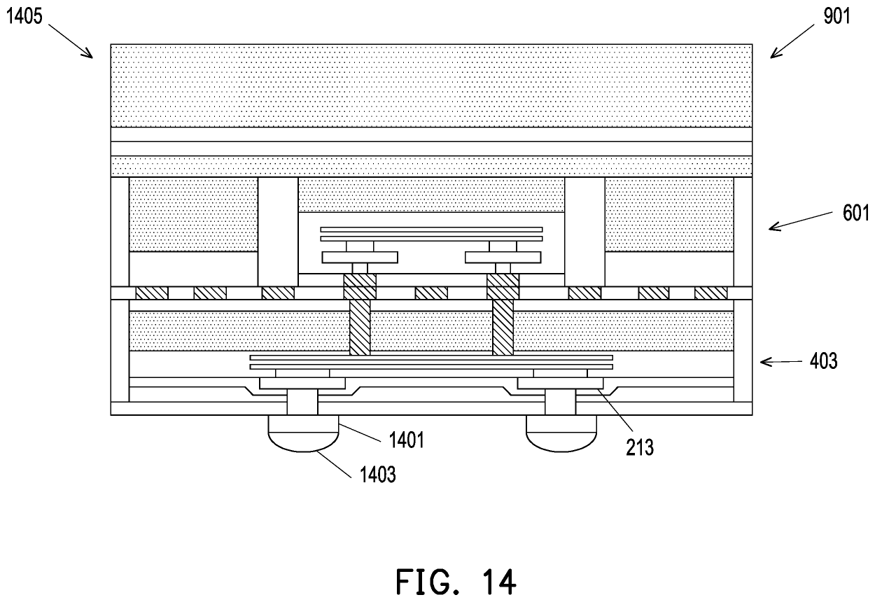

In FIG. 14, first under-bump metallizations (UBMs) 1401 are formed in the first openings 1301 and along the major surface of the first bonding layer 111, and conductive connectors 1403 are formed over the first UBMs 1401. In some embodiments, the first UBMs 1401 have bump portions on and extending along the major surface of the first bonding layer 111, and have via portions extending through the first bonding layer 111, the second bonding layer 207, and the first passivation layer 211 to physically and electrically couple to the first contact pads 213. The first UBMs 1401 may be formed of the same material as the first contact pads 213. In an embodiment, the conductive connectors 1403 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 1403 may include a conductive material such as solder, copper, aluminum, gold, nickel, silver, palladium, tin, the like, or a combination thereof. In some embodiments, the conductive connectors 1403 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 1403 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In accordance with some embodiments of the present disclosure, after forming the conductive connectors 1403 over the first UBMs 1401 a first PoP device 1405 is formed. In an embodiment, the first PoP device 1405 comprises the first carrier structure 901 which supports the second semiconductor device 601 stacked over the first semiconductor device 403 where the first carrier structure 901 is attached to the second semiconductor device 601 by an oxide-to-oxide bond between the first oxide layer 801 and the second oxide layer 903.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

This embodiment may achieve advantages. For Example, by forming the first silicon layer 701 to the first thickness T1, and forming the first oxide layer 801 and the second oxide layer 903 to the first combined thickness TH1 the first PoP device 1405 may achieve improved heat dissipation while maintaining a reduced profile allowing for higher density packaging. The advantages of this embodiment may in part be attributed to the thermal conductivity of the materials used, for example, at a temperature of 300K the thermal conductivity of the first Si/SiO₂ layer and the second Si/SiO₂ layer is about 8 W/(m*K). The first thickness T1 and the first combined thickness TH1 allows for the heat dissipation from the first PoP device 1405 at a rate in a range of about 2 W/(m*K) to about 8 W/(m*K).

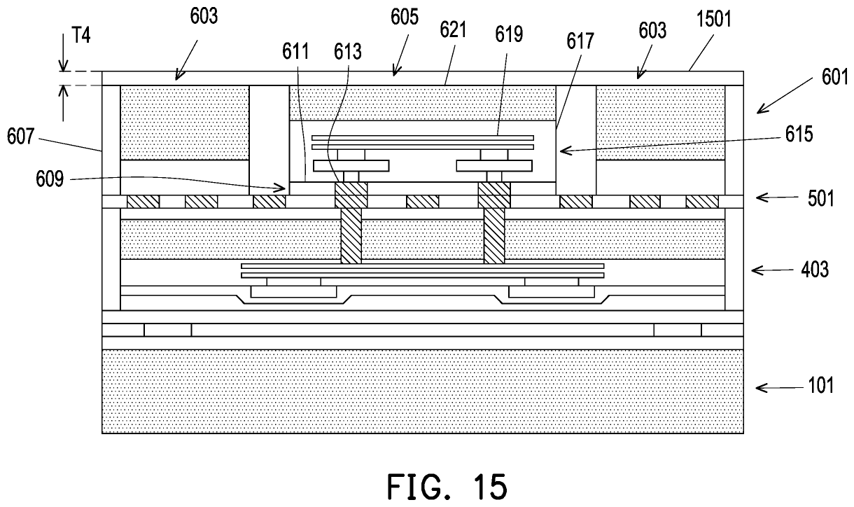

FIGS. 1 through 14 illustrate cross-sectional views of manufacturing the first PoP device 1405 according to some embodiments. Other configurations are also possible. For example, FIGS. 15 through 21 illustrates cross-sectional views of forming a second PoP device 2101 according to some other embodiments. The second PoP device 2101 may be substantially similar to the first PoP device 1405 where like reference numerals indicate like elements formed by like processes. However, in the second PoP device 2101, a second carrier structure 1701, similar to the first carrier structure 901, is bonded to the second semiconductor device 601 by a metal to silicon bond.

In FIG. 15, the second semiconductor device 601 is depicted as attached to the first semiconductor device 403, the first semiconductor device 403 supported by the first carrier substrate 101, by the third bonding layer 501. As further illustrated in FIG. 15, a first insulating buffer layer 1501 is formed over a top surface of the second semiconductor device 601 opposite the first semiconductor device 403; over the dummy dies 603; and over the second encapsulant 607. The first carrier substrate 101, the first semiconductor device 403, the third bonding layer 501, and the second semiconductor device 601 may be formed in a similar manner and from similar materials as discussed above. The first insulating buffer layer 1501 may comprise silicon oxide, or the like, and the first insulating buffer layer 1501 is deposited by CVD, ALD, PVD, or the like. Additionally, the first insulating buffer layer 1501 may be formed to have a fourth thickness T4 in a range of 0.05 μm to 3 μm. It has been observed that thickness greater than the fourth thickness T4 may result in diminished thermal dissipation potential.

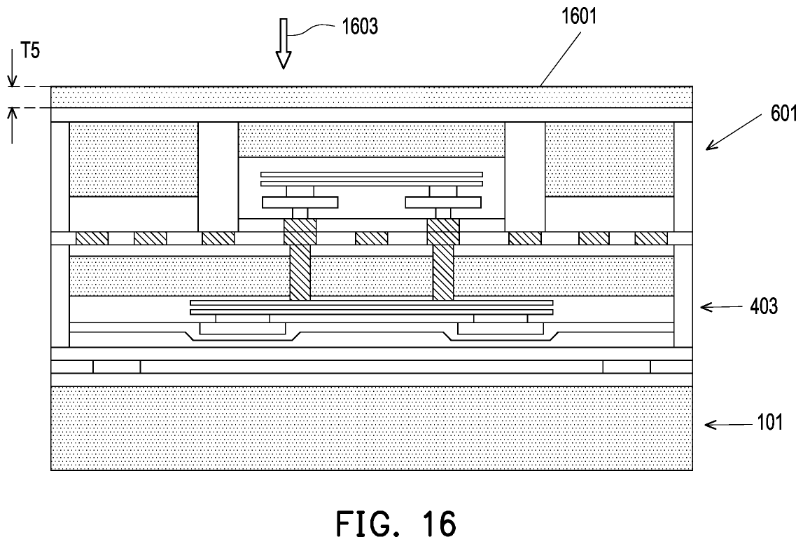

In FIG. 16, a second silicon layer 1601 is formed over the first insulating buffer layer 1501. In accordance with some embodiments, the second silicon layer 1601 is formed by depositing silicon over the first insulating buffer layer 1501 using CVD, HDPCVD, Flowable CVD, spin-on coating, or the like. The second silicon layer 1601 may then be planarized by a third planarization process 1603. In accordance with some embodiments, the third planarization process 1603 may be a mechanical grinding, CMP process, or the like. The third planarization process 1603 may reduce a thickness of the second silicon layer 1601 to a fifth thickness T5 in a range of 0.05 μm to 3 μm. By forming the second silicon layer 1601 to have the fifth thickness T5 discussed above, the second silicon layer 1601 may achieve advantages, such as adequate thermal dissipation in the resulting structure, and to help enhance bonding quality by improving surface roughness. The first insulating buffer layer 1501 may provide electrical insulation between the second silicon layer 1601 and the underlying device dies.

The addition of adding the second silicon layer 1601 improves the heat dissipation capabilities of the subsequently formed PoP device. For example, the relatively high thermal conductivity of the second silicon layer 1601 (e.g., greater than the first insulating buffer layer 1501) may allow for improved heat dissipation from heat generated from devices such as the first semiconductor die 201, the second semiconductor die 605, and other heat generating structures within the subsequently formed PoP device. The utilization of the first silicon layer 701 may allow for more powerful semiconductor dies to be incorporated into the PoP device while maintaining adequate temperatures within the PoP device as to avoid over-heating within the PoP device. Additionally, the utilization of the first silicon layer 701 may allow for improved heat dissipation while occupying a lower profile allowing for higher density packaging while improving or maintaining adequate heat dissipation as to reduce the risk of over-heating within the PoP device. Reducing the risk of over-heating the PoP device is advantageous as it may reduce the risk of thermal degradation within the PoP device as well as reduce the risk of reduced functionality of the PoP device that may be caused by over-heating.

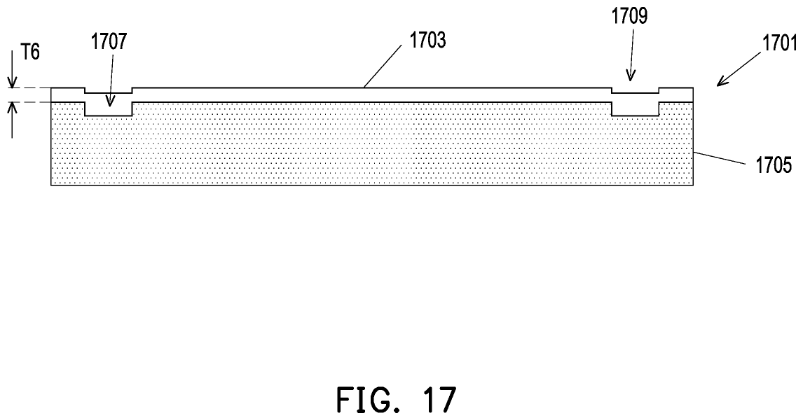

In FIG. 17, a second carrier structure 1701 is illustrated where a first metal layer 1703 is formed over a third carrier substrate 1705. In accordance with some embodiments, the third carrier substrate 1705 comprises silicon or the like. In accordance with some embodiments, prior to forming the first metal layer 1703 over the third carrier substrate 1705, first recesses 1707 may be formed in the third carrier substrate 1705. The first recesses 1707 may be formed in the third carrier substrate 1705 so that when forming the first metal layer 1703 over the third carrier substrate 1705 a height difference between a top surface of the third carrier substrate 1705 and a top surface of the first recesses 1707 in the third carrier substrate 1705 forms third alignment marks 1709. The third alignment marks 1709 may be utilized to facilitate aligning the second carrier structure 1701 to the second semiconductor device 601. The first recesses 1707 may be formed in the third carrier substrate 1705 by etching, milling, laser techniques, a combination thereof, or the like. In accordance with some embodiments, the first metal layer 1703 may be formed over the third carrier substrate 1705 by a sputtering, printing, electro plating, electroless plating, CVD, or the like. In embodiments where first recesses 1707 are formed in the third carrier substrate 1705, recesses in the first metal layer 1703 are formed corresponding to the first recesses 1707, these recesses forming the third alignment marks 1709. The third alignment marks 1709 may be formed as a result of the difference in height between the first recesses 1707 and the remainder of the third carrier substrate 1705 during the deposition of the first metal layer 1703. In an embodiment, the first metal layer 1703 may comprise a metal such as nickel, copper, or the like. Following the formation of the first metal layer 1703, the first metal layer 1703 may have a sixth thickness T6 in a range of 0.05 μm to 3 μm. In accordance with some embodiments, the second carrier structure 1701 may act as a heat dissipation structure for the second semiconductor device 601 and the first semiconductor device 403. Further, the second carrier structure 1701 may have a higher thermal conductivity than the second encapsulant 603. By forming the first metal layer 1703 to the range of the sixth thickness T6, advantages may be achieved. For example, the sixth thickness T6 may provide improved thermal dissipation, in part due to the thermal conductivity of the first metal layer 1703, to the second semiconductor device 601 while still providing adequate bonding capabilities.

In FIG. 18, a second alignment process 1801 is performed to facilitate the attachment of the second carrier structure 1701 to the second silicon layer 1601. In an embodiment, a bottom surface of the second carrier structure 1701 is aligned over a top surface of the second silicon layer 1601 before bonding the first metal layer 1703 to the second silicon layer 1601. In some embodiments, the third alignment marks 1709 may be utilized to facilitate the placement of the second carrier structure 1701 onto the second silicon layer 1601 so that the second carrier structure 1701 is aligned with the second semiconductor device 601.

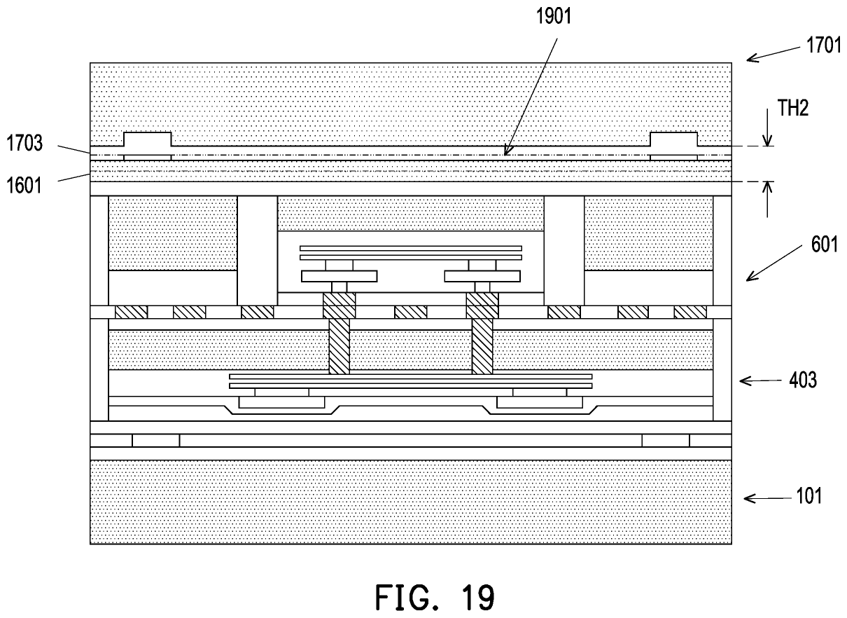

In FIG. 19, the second carrier structure 1701 is attached to the second semiconductor device 601 by directly bonding the first metal layer 1703 to the second silicon layer 1601. As such, the embodiments of FIGS. 15 to 21, the second silicon layer 1601 may also be referred to as a bonding layer. In accordance with some embodiments, the first metal layer 1703 is bonded to the second silicon layer 1601 by performing a first thermal anneal process. The first thermal anneal process may be performed at a temperature from room temperature (e.g. around 20° C.) to 400° C. for a duration from 0.5 hours to 12 hours, so that the first metal layer 1703 reacts with the second silicon layer 1601 to form a metal-to-silicon bond. In accordance with some embodiments, the metal-to-silicon bond forms a metal silicide 1901 at the interface between the first metal layer 1703 and the second silicon layer 1601. Following the bonding of the first metal layer 1703 to the second silicon layer 1601, the first metal layer 1703 and the second silicon layer 1601 have a second combined thickness TH2 in a range of 1 μm to 6 μm. By bonding the first metal layer 1703 to the second silicon layer 1601 such that the first metal layer 1703 and the second silicon layer 1601 have the second combined thickness TH2, the first metal layer 1703 and the second silicon layer 1601 may provide improved thermal dissipation and adequate bonding strength between the second semiconductor device 601 and the second carrier structure 1701. Thicknesses below the second combined thickness TH2 may not provide adequate bonding between the second semiconductor device 601 and the second carrier structure 1701 and thicknesses above the second combined thickness TH2 may unnecessarily increase the size of the PoP device.

In accordance with some embodiments, following the bonding of the second carrier structure 1701 to the second semiconductor device 601 first gaps may be present between the second silicon layer 1601 and the first metal layer 1703. The first gaps are formed as the result of the difference in the height between the first recesses 1707 and the remainder of the third carrier substrate 1705 during the deposition of the first metal layer 1703 when forming the third alignment marks 1709 of the second carrier structure 1701 and the second carrier structure 1701 when bonded to a planar surface of the second silicon layer 1601, the first gaps are formed at locations between the second silicon layer 1601 and the second carrier structure 1701 corresponding to locations of the third alignment marks 1709.

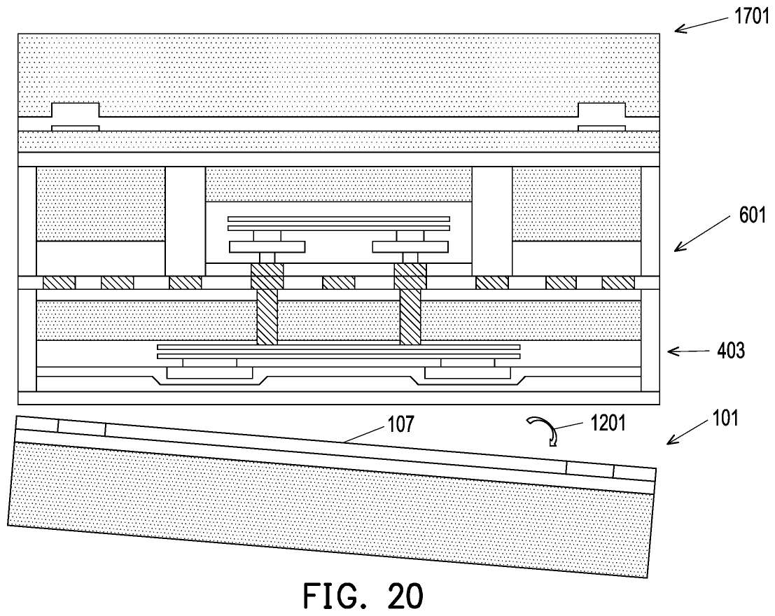

In FIG. 20, the debonding process 1201 is performed to remove the first carrier substrate 101 from the first semiconductor device 403. In an embodiment, the debonding includes projecting a light such as a laser light or an ultraviolet (UV) light on the release layer 107 so that the release layer 107 decomposes and the first carrier substrate 101 may be removed.

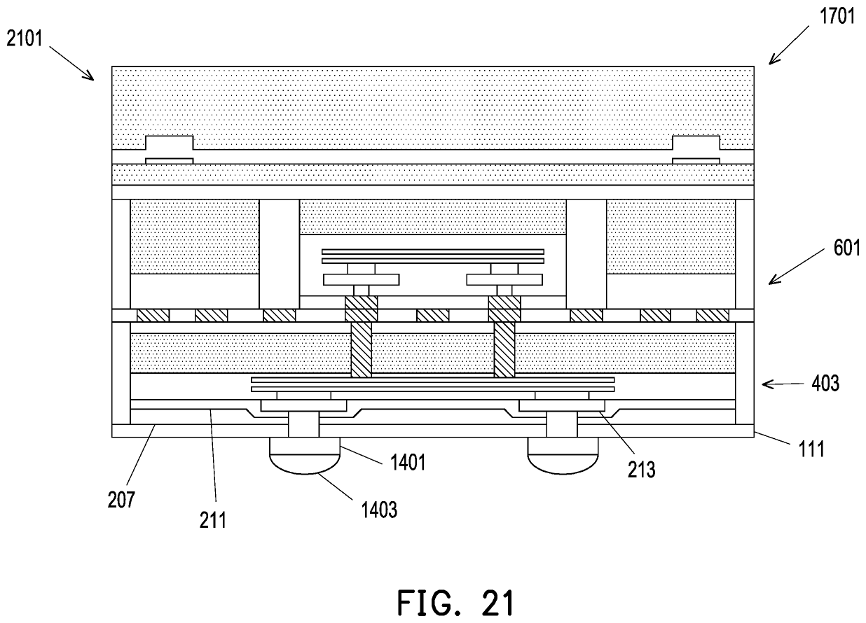

In FIG. 21, a second PoP device 2101 is illustrated following a formation of the first UBMs 1401 and the conductive connectors 1403. The first UBMs 1401 may be formed in a similar manner and from similar materials as discussed above with respect to FIG. 14. The conductive connectors 1403 may be formed in a similar manner and from similar materials as discussed above with respect to FIG. 14. In an embodiment, the second PoP device 2101 comprises the second carrier structure 1701 which supports the second semiconductor device 601 stacked over the first semiconductor device 403 where the second carrier structure 1701 is attached to the second semiconductor device 601 by bonding the first metal layer 1703 to the second silicon layer 1601.

This embodiment may achieve advantages. For example, by forming the second silicon layer 1601 and the first metal layer 1703 to the second combined thickness TH2 the second PoP device 2101 may achieve improved heat dissipation while maintaining a reduced profile allowing for higher density packaging. The advantages of this embodiment may in part be attributed to the relatively high thermal conductivity of the materials used. For example, at a temperature of 300K the thermal conductivity of the nickel is about 91 W/(m*K). The second combined thickness TH2 allows for the heat dissipation from the second PoP device 2101 at a rate greater than 91 W/(m*K).

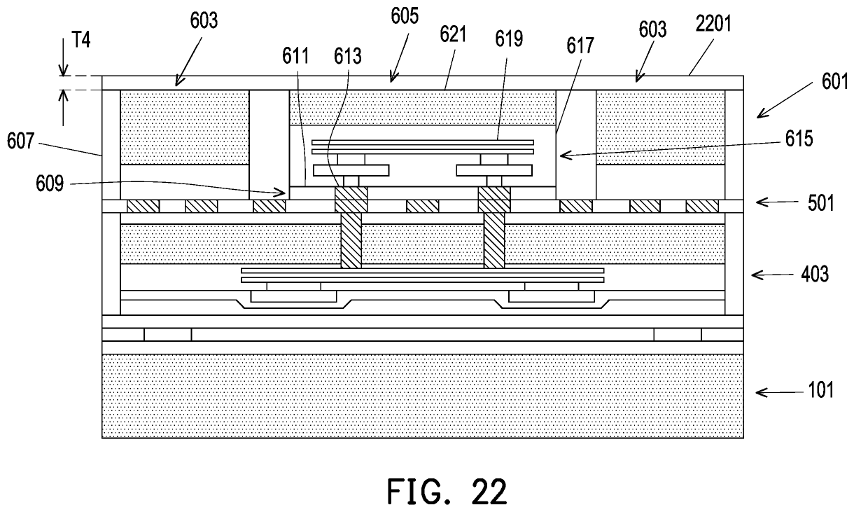

Further, FIGS. 22 through 28 illustrates cross-sectional views of forming a third PoP device 2801 according to some other embodiments. The third PoP device 2801 may be substantially similar to the first PoP device 1405 where like reference numerals indicate like elements formed by like processes. In the third PoP device 2801, a third carrier structure 2401, similar to the first carrier structure 901, is bonded to the second semiconductor device 601 by a metal-to-metal bond.

In FIG. 22, the second semiconductor device 601 is depicted as attached to the first semiconductor device 403, the first semiconductor device 403 supported by the first carrier substrate 101, by the third bonding layer 501 and a second insulating buffer layer 2201 formed over a top surface of the second semiconductor device 601 opposite the first semiconductor device 403. The first carrier substrate 101, the first semiconductor device 403, the third bonding layer 501, and the second semiconductor device 601 may be formed in a similar manner and from similar materials as discussed above.

In accordance with some embodiments, the second insulating buffer layer 2201 may be formed over the top surface of the second semiconductor device 601 by CVD, ALD, PVD, thermal oxidation, or the like. The second insulating buffer layer 2201 may comprise an oxide material such as silicon oxide, or the like.

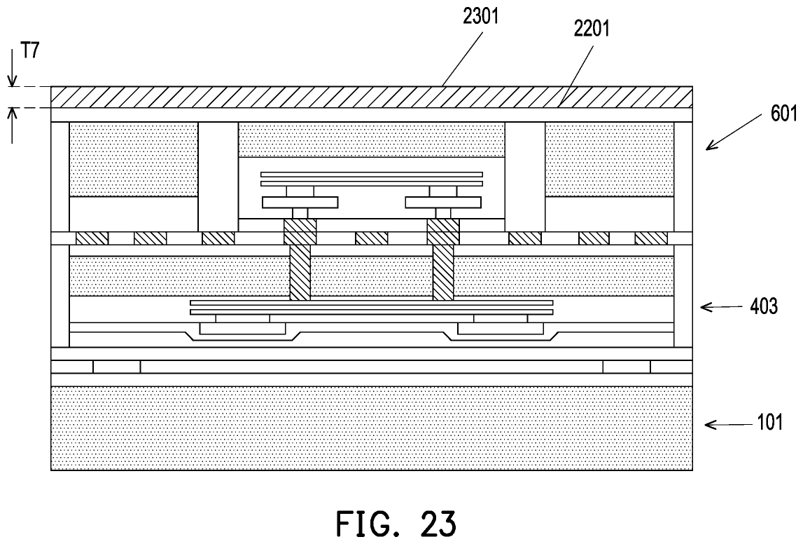

In FIG. 23, a second metal layer 2301 is formed over a top surface of the second insulating buffer layer 2201. In an embodiment, the second metal layer 2301 may be formed by forming a seed layer over the second insulating buffer layer 2201, the seed layer may be a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. The second metal layer 2301 may then be formed by plating a metal onto the seed layer, the plating may be electroplating or electroless plating, or the like. The metal may be copper, or the like. After plating the metal onto the seed layer, the second metal layer 2301 may have a seventh thickness T7 in a range of 0.05 μm to 10 μm. By forming the second metal layer 2301 to the range of the seventh thickness T7, advantages may be achieved. For example, the seventh thickness T7 may provide improved thermal dissipation, in part due to the thermal conductivity of the second metal layer 2301, to the second semiconductor device 601 while still providing adequate bonding capabilities.

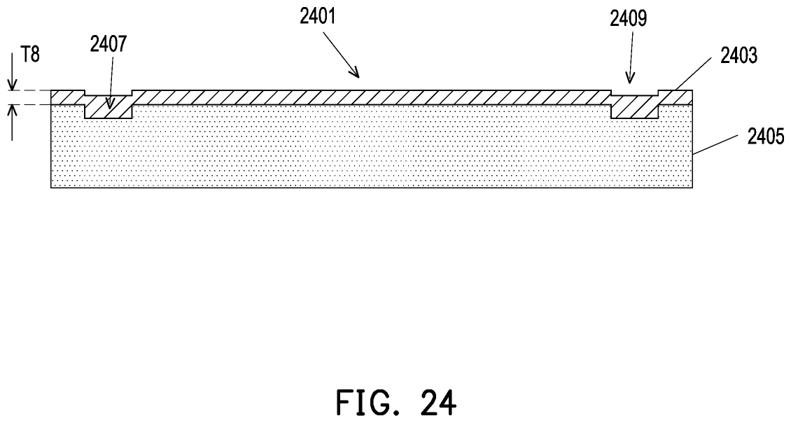

In FIG. 24, a third carrier structure 2401 is illustrated where a third metal layer 2403 is formed over a fourth carrier substrate 2405. In accordance with some embodiments, the fourth carrier substrate 2405 comprises silicon, or the like. In accordance with some embodiments, prior to forming the third metal layer 2403 over the fourth carrier substrate 2405, second recesses 2407 may be formed in the fourth carrier substrate 2405. The second recesses 2407 may be formed in the fourth carrier substrate 2405 so that when forming the third metal layer 2403 over the fourth carrier substrate 2405 a height difference between a top surface of the fourth carrier substrate 2405 and a top surface of the second recesses 2407 in the fourth carrier substrate 2405 forms fourth alignment marks 2409. The fourth alignment marks 2409 may be utilized to facilitate aligning the third carrier structure 2401 to the second semiconductor device 601. The second recesses 2407 may be formed in the fourth carrier substrate 2405 by etching, milling, laser techniques, a combination thereof, or the like. In accordance with some embodiments, the third metal layer 2403 may be formed over the fourth carrier substrate 2405 by a sputtering, printing, electro plating, electroless plating, CVD, or the like. In embodiments where second recesses 2407 are formed in the fourth carrier substrate 2405, recesses in the third metal layer 2403 are formed corresponding to the second recesses 2407, these recesses forming the fourth alignment marks 2409. In an embodiment, the third metal layer 2403 may comprise a metal such as copper, or the like. Following the formation of the third metal layer 2403, the third metal layer 2403 may have a eighth thickness T8 in a range of 0.05 μm to 10 μm. In accordance with some embodiments, the third carrier structure 2401 may act as a heat dissipation structure for the second semiconductor device 601 and the first semiconductor device 403. Further, the third carrier structure 2401 may have a higher thermal conductivity than the second encapsulant 603. By forming the third metal layer 2403 to the range of the eighth thickness T8, advantages may be achieved. For example, the eighth thickness T8 may provide improved thermal dissipation, in part due to the thermal conductivity of the third metal layer 2403, to the second semiconductor device 601 while still providing adequate bonding capabilities.

In FIG. 25, a third alignment process 2501 is performed to facilitate the attachment of the third carrier structure 2401 to the second metal layer 2301. In an embodiment, a bottom surface of the third carrier structure 2401 is aligned over a top surface of the second metal layer 2301 before bonding the third metal layer 2403 to the second metal layer 2301. In some embodiments, the fourth alignment marks 2409 may be utilized to facilitate the placement of the third carrier structure 2401 onto the second metal layer 2301 so that the third carrier structure 2401 is aligned with the second semiconductor device 601.

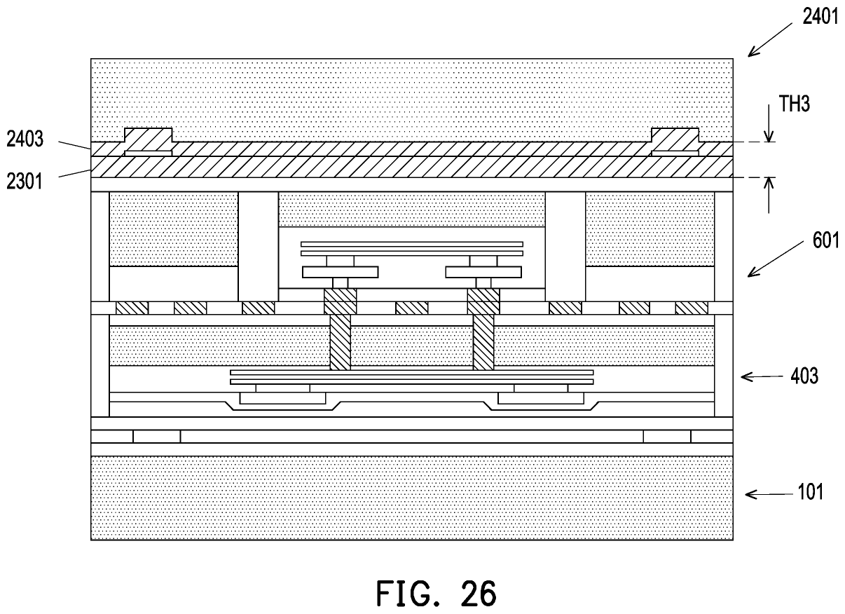

In FIG. 26, the third carrier structure 2401 is attached to the second semiconductor device 601 by bonding the third metal layer 2403 to the second metal layer 2301. In accordance with some embodiments, the third metal layer 2403 is bonded to the second metal layer 2301 by performing a second thermal anneal process. The second thermal anneal process may be performed at a temperature from room temperature (e.g. around 20° C.) to 400° C. for a duration from 0.5 hours to 12 hours, so that the third metal layer 2403 reacts with the second metal layer 2301 to form a metal-to-metal bond between the third metal layer 2403 and the second metal layer 2301. Following the formation of the metal-to-metal bond between the second metal layer 2301 and the third metal layer 2403, the second metal layer 2301 and the third metal layer 2403 may have a third combined thickness TH3 in a range from 0.05 μm to 20 μm. The second metal layer 2301 and the third metal layer 2403 having the third combined thickness TH3 may provide improved thermal dissipation and adequate bonding strength between the second semiconductor device 601 and the third carrier structure 2401. Thicknesses below the third combined thickness TH3 may not provide adequate bonding between the second semiconductor device 601 and the third carrier structure 2401, and thicknesses above the third combined thickness TH3 may unnecessarily increase the size of the PoP device.

In accordance with some embodiments, following the bonding of the third carrier structure 2401 to the second semiconductor device 601 second gaps may be present between the second metal layer 2301 and the third metal layer 2403. The second gaps are formed as the result of the difference in the height between the second recesses 2407 and the remainder of the fourth carrier substrate 2405 during the deposition of the third metal layer 2403 when forming the fourth alignment marks 2409 of the third carrier structure 2401 and the third carrier structure 2401 when bonded to a planar surface of the second metal layer 2301, the second gaps are formed at locations between the second metal layer 2301 and the third carrier structure 2401 corresponding to locations of the fourth alignment marks 2409.

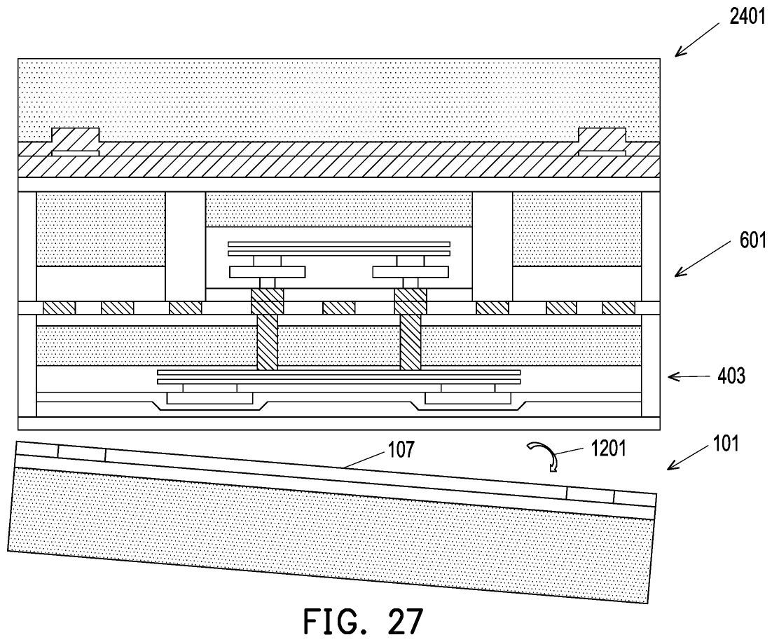

In FIG. 27, the debonding process 1201 is performed to remove the first carrier substrate 101 from the first semiconductor device 403. In an embodiment, the debonding includes projecting a light such as a laser light or an ultraviolet (UV) light on the release layer 107 so that the release layer 107 decomposes and the first carrier substrate 101 may be removed.

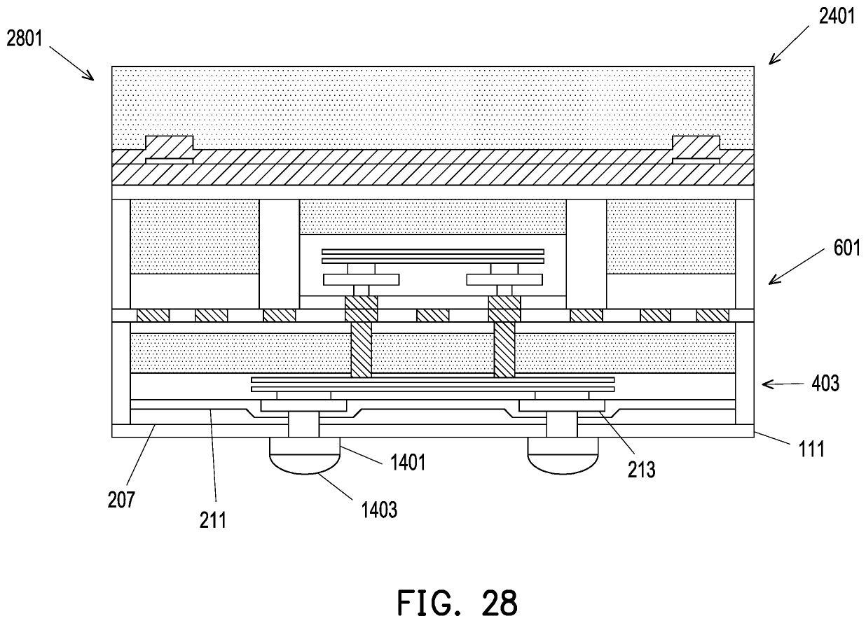

In FIG. 28, a third PoP device 2801 is illustrated following a formation of the first UBMs 1401 and the conductive connectors 1403. The first UBMs 1401 may be formed in a similar manner and from similar materials as discussed above with respect to FIG. 14. The conductive connectors 1403 may be formed in a similar manner and from similar materials as discussed above with respect to FIG. 14. In an embodiment, the third PoP device 2801 comprises the third carrier structure 2401 which supports the second semiconductor device 601 stacked over the first semiconductor device 403 where the third carrier structure 2401 is attached to the second semiconductor device 601 by bonding the third metal layer 2403 to the second metal layer 2301.

This embodiment may achieve advantages. For example, by forming the second metal layer 2301 and the third metal layer 2403 to the third combined thickness TH3 the third PoP device 2801 may achieve improved heat dissipation while maintaining a reduced profile allowing for higher density packaging. The advantages of this embodiment may in part be attributed to the thermal conductivity of the materials used, for example, at a temperature of 300K the thermal conductivity of the copper is about 400 W/(m*K). The third combined thickness TH3 allows for the heat dissipation from the third PoP device 2801 at a rate greater than 400 W/(m*K).

Embodiments may achieve advantages. Embodiments of the present disclosure utilize various materials at various thicknesses and bonding processes to adhere the second semiconductor device 601 to various carrier structures in order to improve the heat dissipation capabilities of the formed PoP devices. By selecting the materials and thicknesses and bonding methods the various carrier structures are able to provide adequate heat dissipation depending on the thermal needs of the formed PoP devices, thereby improving the performance and reliability of the formed PoP devices.

In accordance with some embodiments of the present disclosure a semiconductor device including: a first semiconductor package including: a first interconnect structure on a first semiconductor substrate; through substrate vias electrically coupled to the first interconnect structure extending through the first semiconductor substrate; and a second semiconductor package directly bonded to the first semiconductor package, the second semiconductor package including a second semiconductor substrate and a second interconnect structure on the second semiconductor substrate; and a silicon layer on a side of the second semiconductor package that is opposite to the first semiconductor package; and a heat dissipation structure attached to the silicon layer. In an embodiment the silicon layer has a thickness in a range from 1 μm to 6 μm. In an embodiment further including a first oxide bonding layer in direct physical contact with the silicon layer; and a second oxide bonding layer in direct physical contact with the first oxide bonding layer, the second oxide bonding layer being in physical contact with the heat dissipation structure. In an embodiment further including a metal bonding layer directly bonded to the silicon layer, the metal bonding layer being in direct physical contact with the heat dissipation structure. In an embodiment the second semiconductor package further includes an insulating buffer layer on the second semiconductor substrate, the insulating buffer layer being in direct physical contact with the silicon layer. In an embodiment the second semiconductor package further includes a plurality of dummy dies, the dummy dies adjacent to the second semiconductor die. In an embodiment the first semiconductor package is directly bonded to the second semiconductor package by a bonding layer, the bonding layer including: bonding pads electrically coupling the first semiconductor die to the second semiconductor die; and dummy pads.

In accordance with some embodiments of the present disclosure a method of manufacturing a semiconductor device including: forming a first bonding layer over a first semiconductor die, the first semiconductor die including a first interconnect structure on a first semiconductor substrate; bonding a second semiconductor die to the first bonding layer, the second semiconductor die including a second interconnect structure on a second semiconductor substrate; encapsulating the second semiconductor die in an encapsulant; depositing an insulating buffer layer over the second semiconductor die and the encapsulant; forming a second bonding layer over a top surface of the second semiconductor die and the encapsulant, wherein the second bonding layer has a higher thermal conductivity than the insulating buffer layer; and directly bonding a third bonding layer of a heat dissipation structure to the second bonding layer, wherein the heat dissipation structure includes the third bonding layer on a silicon substrate. In an embodiment the forming the second bonding layer includes depositing a silicon layer over the insulating buffer layer and bonding the third bonding layer to the silicon layer. In an embodiment the bonding the third bonding layer of the heat dissipation structure to the silicon layer includes forming a metal-to-silicon bond between the silicon layer and the third bonding layer. In an embodiment following forming the metal-to-silicon bond between the silicon layer and the third bonding layer, the silicon layer and the third bonding layer have a combined thickness between 1 μm to 6 μm. In an embodiment the silicon layer has a thickness in a range from 1 μm to 6 μm. In an embodiment the second bonding layer includes a first metal layer and the third bonding layer includes a second metal layer, and wherein the bonding the third bonding layer to the second bonding layer forms a metal-to-metal bond. In an embodiment the first bonding layer includes active bonding pads and dummy bonding pads, wherein the active bonding pads are used in the bonding the second semiconductor die to the first bonding layer and the active bonding pads electrically couple the first semiconductor die to the second semiconductor die.

In accordance with some embodiments of the present disclosure a method of manufacturing a semiconductor device including: bonding a first semiconductor die to a first carrier substrate, the first semiconductor die including: a first interconnect structure, a first semiconductor substrate over the first interconnect structure; and through substrate vias extending from the first interconnect structure through the first semiconductor substrate; bonding a second semiconductor die to the first semiconductor die, the second semiconductor die including: a second interconnect structure, and a second semiconductor substrate over the second interconnect structure; encapsulating the second semiconductor die in a molding compound; depositing a silicon layer over the molding compound and the second semiconductor die; bonding a second carrier substrate to the silicon layer; and performing a debonding process to release the first carrier substrate from the first semiconductor die. In an embodiment further including: following the debonding process exposing a conductive contact pad of the first interconnect structure; and forming an under-bump metallization in contact with the conductive contact pad. In an embodiment the bonding the second carrier substrate to the silicon layer includes: depositing a first oxide layer on the silicon layer; depositing a second oxide layer on the second carrier substrate; and directly bonding the first oxide layer to the second oxide layer. In an embodiment bonding the second carrier substrate to the silicon layer further includes activating a first surface of the first oxide layer or activating a second surface of the second oxide layer prior to directly bonding the first oxide layer to the second oxide layer. In an embodiment the bonding the second semiconductor die to the first semiconductor die further includes bonding contact pads of the second interconnect structure to metal bond pads, the metal bond pads being in direct physical contact with the through substrate vias and electrically coupling the first semiconductor die to the second semiconductor die. In an embodiment bonding the second carrier substrate includes a bonding a metal layer directly to the silicon layer, wherein the metal layer contacts the second carrier substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first semiconductor package comprising:
a first interconnect structure on a first semiconductor substrate;
through substrate vias electrically coupled to the first interconnect structure extending through the first semiconductor substrate; and
a second semiconductor package directly bonded to the first semiconductor package, the second semiconductor package comprising a second semiconductor substrate and a second interconnect structure on the second semiconductor substrate; and
a silicon layer on a side of the second semiconductor package that is opposite to the first semiconductor package; and
a heat dissipation structure attached to the silicon layer.

2. The device of claim 1, wherein the silicon layer has a thickness in a range from 1 μm to 6 μm.

3. The device of claim 1, further comprising:
a first oxide bonding layer in direct physical contact with the silicon layer; and
a second oxide bonding layer in direct physical contact with the first oxide bonding layer, the second oxide bonding layer being in physical contact with the heat dissipation structure.

4. The device of claim 1, further comprising a metal bonding layer directly bonded to the silicon layer, the metal bonding layer being in direct physical contact with the heat dissipation structure.

5. The device of claim 1, wherein the second semiconductor package further comprises an insulating buffer layer on the second semiconductor substrate, the insulating buffer layer being in direct physical contact with the silicon layer.

6. The device of claim 1, wherein the second semiconductor package further comprises a plurality of dummy dies, the dummy dies adjacent to the second semiconductor die.

7. The device of claim 1, wherein the first semiconductor package is directly bonded to the second semiconductor package by a bonding layer, the bonding layer comprising:
bonding pads electrically coupling the first semiconductor die to the second semiconductor die; and
dummy pads.

8. A method of manufacturing a semiconductor device comprising:
forming a first bonding layer over a first semiconductor die, the first semiconductor die comprising a first interconnect structure on a first semiconductor substrate;
bonding a second semiconductor die to the first bonding layer, the second semiconductor die comprising a second interconnect structure on a second semiconductor substrate;
encapsulating the second semiconductor die in an encapsulant;
depositing an insulating buffer layer over the second semiconductor die and the encapsulant;
forming a second bonding layer over a top surface of the second semiconductor die and the encapsulant, wherein the second bonding layer has a higher thermal conductivity than the insulating buffer layer; and
directly bonding a third bonding layer of a heat dissipation structure to the second bonding layer, wherein the heat dissipation structure comprises the third bonding layer on a silicon substrate.

9. The method of claim 8, wherein the forming the second bonding layer comprises depositing a silicon layer over the insulating buffer layer and bonding the third bonding layer to the silicon layer.

10. The method of claim 9, wherein the bonding the third bonding layer of the heat dissipation structure to the silicon layer comprises forming a metal-to-silicon bond between the silicon layer and the third bonding layer.

11. The method of claim 10, wherein following forming the metal-to-silicon bond between the silicon layer and the third bonding layer, the silicon layer and the third bonding layer have a combined thickness between 1 μm to 6 μm.

12. The method of claim 9, wherein the silicon layer has a thickness in a range from 1 μm to 6 μm.

13. The method of claim 8, wherein the second bonding layer comprises a first metal layer and the third bonding layer comprises a second metal layer, and wherein the bonding the third bonding layer to the second bonding layer forms a metal-to-metal bond.

14. The method of claim 8, wherein the first bonding layer comprises active bonding pads and dummy bonding pads, wherein the active bonding pads are used in the bonding the second semiconductor die to the first bonding layer and the active bonding pads electrically couple the first semiconductor die to the second semiconductor die.

15. A method of manufacturing a semiconductor device comprising:
bonding a first semiconductor die to a first carrier substrate, the first semiconductor die comprising:
a first interconnect structure, a first semiconductor substrate over the first interconnect structure; and
through substrate vias extending from the first interconnect structure through the first semiconductor substrate;
bonding a second semiconductor die to the first semiconductor die, the second semiconductor die comprising:
a second interconnect structure, and
a second semiconductor substrate over the second interconnect structure encapsulating the second semiconductor die in a molding compound;
depositing a silicon layer over the molding compound and the second semiconductor die;
bonding a second carrier substrate to the silicon layer; and
performing a debonding process to release the first carrier substrate from the first semiconductor die.

16. The method of claim 15, further comprising:
following the debonding process exposing a conductive contact pad of the first interconnect structure; and
forming an under-bump metallization in contact with the conductive contact pad.

17. The method of claim 15, wherein the bonding the second carrier substrate to the silicon layer comprises:
depositing a first oxide layer on the silicon layer;
depositing a second oxide layer on the second carrier substrate; and
directly bonding the first oxide layer to the second oxide layer.

18. The method of claim 17, wherein bonding the second carrier substrate to the silicon layer further comprises activating a first surface of the first oxide layer or activating a second surface of the second oxide layer prior to directly bonding the first oxide layer to the second oxide layer.

19. The method of claim 15, wherein the bonding the second semiconductor die to the first semiconductor die further comprises bonding contact pads of the second interconnect structure to metal bond pads, the metal bond pads being in direct physical contact with the through substrate vias and electrically coupling the first semiconductor die to the second semiconductor die.

20. The method of claim 15, wherein bonding the second carrier substrate comprises a bonding a metal layer directly to the silicon layer, wherein the metal layer contacts the second carrier substrate.
